(19) United States
(12) Patent Application Publication
(10) Pub. No.: US 2012/0247949 A1
(43) Pub. Date: Oct. 4, 2012

(54) FILM FORMING METHOD, RESPUTTERING METHOD, AND FILM FORMING APPARATUS

(76) Inventors: Takashi SAKUMA, Nirasaki City (JP); Tadahiro Ishizaka, Nirasaki City (JP); Tatsuo Hatano, Nirasaki City (JP); Shiro Hayashi, Nirasaki City (JP); Toshiaki Fujisato, Nirasaki City (JP); Hiroyuki Yokohara, Nirasaki City (JP); Hiroyuki Toshima, Nirasaki City (JP)

(21) Appl. No.: 13/433,527

(22) Filed: Mar. 29, 2012

(30) Foreign Application Priority Data
Mar. 30, 2011 (JP) 2011-075126

(51) Int. Cl. C23C 14/34

(52) U.S. Cl. 204/192.15; 204/298.02; 204/298.11

(57) ABSTRACT

A film forming method includes depositing a metal thin film on a target substrate by generating an inductively coupled plasma in a processing chamber while introducing a plasma generating gas in the processing chamber with the substrate disposed on a placing table, by supplying DC power to a metal target from a DC power source, and by applying high-frequency bias to the placing table. A resputtering method includes resputtering the deposited metal thin film by stopping the generating of the inductively coupled plasma, by stopping the power supply from the DC power source, and by applying the high-frequency bias to the placing table while introducing the plasma generating gas in the processing chamber to form a capacitively coupled plasma in the processing chamber and by attracting ions of the plasma generating gas to the target substrate where the metal thin film is deposited.

### CROSS-REFERENCE TO RELATED APPLICATIONS

This application is based on and claims priority from Japanese Patent Application No. 2011-075126, filed on Mar. 30, 2011 with the Japanese Patent Office, the disclosure of which is incorporated herein in its entirety by reference.

### TECHNICAL FIELD

The present disclosure relates to a film forming method, a resputtering method, and a film forming apparatus that use an ionized sputtering.

### BACKGROUND

Copper (Cu) has been used recently in manufacturing of semiconductor devices as a wiring material according to demands on a high speed, fineness of wiring patterns, and high integration of semiconductor devices.

As a method of forming a Cu wiring, a technique has been proposed in which a barrier film made of, for example, tantalum (Ta), titanium (Ti), a tantalum nitride film (TaN), and a titanium nitride film (TiN), is formed on the overall interlayer dielectric film having trenches or holes by a plasma sputtering which is a physical vapor deposition (PVD), a Cu seed film is formed on the barrier film by the plasma sputtering, the trenches or the holes are fully filled by performing a Cu plating thereon, and then an extra copper thin film on the surface of a wafer is removed by performing a polishing processing using, for example, a chemical mechanical polishing (CMP) processing. See, for example, Japanese Patent Application Laid-Open No. 2006-148075.

As a plasma sputtering apparatus used in forming the barrier film or the Cu seed film, an inductively coupled plasma sputtering apparatus capable of acquiring high plasma density and forming a film at a high rate, has been used. See, for example, Japanese Patent Application Laid-Open No. 2008-98284.

However, in the plasma sputtering, the film is formed by ionizing metallic particles discharged from a target by plasma and vertically inputting metallic ions to a substrate to be processed (“a target substrate”) using a bias applied to a placing table. As a result, the step coverage is generally deteriorated forming a relatively thicker film at the bottoms or the shoulders of the trenches or the holes, and a relatively thinner film at the side walls thereof. Hence, as shown in Japanese Patent Application Laid-Open No. 2008-98284, a resputtering technique has been used in which, after deposition of the barrier film, the discharge of the metallic particles from the target is stopped and a plasma generating gas such as an argon gas is introduced to the target substrate. As a result, the film at the bottoms of the trenches or the holes are sputtered and reattached to the side walls of the trenches or the holes, thereby thickening the film while improving the uniformity of the film.

### SUMMARY

An exemplary embodiment of the present disclosure provides a film forming method of forming a metal thin film on a target substrate having trenches and/or holes by using a film forming apparatus including a processing chamber in which the target substrate is received, a placing table configured to dispose the target substrate in the processing chamber, a gas introducing mechanism configured to introduce a plasma generating gas in the processing chamber, an inductively coupled plasma generating mechanism configured to generate an inductively coupled plasma of the plasma generating gas in the processing chamber, a metal target made of metal of a metallic film to be formed, a DC power source configured to supply DC power to the metal target, and a bias power source configured to apply high-frequency bias for attracting ions in the plasma generated in the processing chamber to the placing table. The method includes: depositing a metal thin film on the target substrate by generating the inductively coupled plasma in the processing chamber using the inductively coupled plasma generating mechanism while introducing the plasma generating gas in the processing chamber with the target substrate disposed on the placing table, by supplying the DC power to the metal target from the DC power source, and by applying high-frequency bias to the placing table using the bias power source; and resputtering the deposited metal thin film by stopping the generating of the inductively coupled plasma generated using the inductively coupled plasma generating mechanism, by stopping the power supply from the DC power source, and by applying the high-frequency bias to the placing table by the bias power source while introducing the plasma generating gas in the processing chamber to generate a capacitively coupled plasma in the processing chamber and by attracting ions of the plasma generating gas to the target substrate where the metal thin film is deposited.

The foregoing summary is illustrative only and is not intended to be in any way limiting. In addition to the illustrative aspects, embodiments, and features described above, further aspects, embodiments, and features will become apparent by reference to the drawings and the following detailed description.

### BRIEF DESCRIPTION OF THE DRAWINGS

FIG. 1 is a cross-sectional view illustrating an example of a film forming apparatus that performs a film forming method according to an exemplary embodiment of the present disclosure.

FIG. 2 is an enlarged cross-sectional view illustrating a placing table of the film forming apparatus of FIG. 1.

FIG. 3 is a flowchart describing processes of a film forming method according to an exemplary embodiment of the present disclosure.

FIG. 4 is a schematic view describing a comparison between an inductively coupled plasma mode and a capacitively coupled plasma mode in the film forming apparatus of FIG. 1.

FIG. 5 is a schematic view describing a comparison of the states of trenches of a wafer in the case of a resputtering in the inductively coupled plasma mode and in the case of a resputtering in the capacitively coupled plasma mode.

FIG. 6 is a schematic view describing a comparison of directions of ions attracted to edges of a wafer in a case where an electrode part of a placing table body is insulated from a bias ring installed around the electrode part and in a case where the electrode part is conductively communicated with the bias ring.

FIG. 7 is a SEM photograph illustrating a comparison of resputtering states of trenches of edges of a wafer in the case where the electrode part of the placing table body is insulated from the bias ring installed around the electrode part and in the case where the electrode part is conductively communicated with the bias ring.

FIG. 8 is a SEM photograph illustrating a comparison of trenches after resputtering in the inductively coupled plasma mode and the capacitively coupled plasma mode.

FIG. 9 is a diagram illustrating a relationship between self biased voltage Vdc and a facet angle of a trench during resputtering.

### DETAILED DESCRIPTION

In the following detailed description, reference is made to the accompanying drawing, which form a part hereof. The illustrative embodiments described in the detailed description, drawing, and claims are not meant to be limiting. Other embodiments may be utilized, and other changes may be made, without departing from the spirit or scope of the subject matter presented here.

The inductively coupled plasma generated by the inductively coupled plasma sputtering apparatus has a high density, and the self biased voltage Vdc of the target substrate is inherently low. As a result, the self biased voltage Vdc may not be sufficiently acquired even if the bias power is increased. Moreover the resputtered metals are reattached to the vicinity of entrances of the trenches or the holes to form an overhang, and the sputtered metallic particles may not be provided into the trenches or the holes, which is problematic.

The present disclosure has been made in an effort to provide a film forming method and a resputtering method which are capable of preventing an overhang at the entrances of the trenches and/or the holes when the film is formed on a target substrate by an inductively coupled plasma sputtering apparatus.

The present disclosure has been made in an effort to provide a film forming apparatus capable of preventing an overhang at the entrances of the trenches and/or the holes with an inductively coupled plasma sputtering apparatus.

An exemplary embodiment of the present disclosure provides a film forming method of forming a metal thin film on a target substrate having trenches and/or holes by using a film forming apparatus. The film forming apparatus of the exemplary embodiment includes a processing chamber in which the target substrate is received, a placing table configured to dispose the target substrate in the processing chamber, a gas introducing mechanism configured to introduce a plasma generating gas in the processing chamber, an inductively coupled plasma generating mechanism configured to generate an inductively coupled plasma of the plasma generating gas in the processing chamber, a metal target made of metal of a metallic film to be formed, a DC power source configured to supply DC power to the metal target, and a bias power source configured to apply high-frequency bias for attracting ions in the plasma generated in the processing chamber to the placing table. The method of the exemplary embodiment includes depositing a metal thin film on the target substrate by generating the inductively coupled plasma in the processing chamber using the inductively coupled plasma generating mechanism while introducing the plasma generating gas in the processing chamber with the target substrate disposed on the placing table, by supplying the DC power to the metal target from the DC power source, and by applying high-frequency bias to the placing table using the bias power source; and resputtering the deposited metal thin film by stopping the generating of the inductively coupled plasma using the inductively coupled plasma generating mechanism, by stopping the power supply from the DC power source, and by applying the high-frequency bias to the placing table using the bias power source while introducing the plasma generating gas in the processing chamber to generate a capacitively coupled plasma in the processing chamber and by attracting ions of the plasma generating gas to the target substrate where the metal thin film is deposited.

Another exemplary embodiment of the present disclosure provides a resputtering method of resputtering a metal thin film after depositing the metal thin film on a target substrate having trenches and/or holes by using a film forming apparatus. The film forming apparatus includes a processing chamber in which the target substrate is received, a placing table configured to dispose the target substrate in the processing chamber, a gas introducing mechanism configured to introduce a plasma generating gas in the processing chamber, an inductively coupled plasma generating mechanism configured to generate an inductively coupled plasma of the plasma generating gas in the processing chamber, a metal target made of metal of a metallic film to be formed, a DC power source configured to supply DC power to the metal target, and a bias power source configured to apply high-frequency bias for attracting ions in the plasma generated in the processing chamber to the placing table. The method includes resputtering the deposited metal thin film by applying the high-frequency bias to the placing table using the bias power source while introducing the plasma generating gas in the processing chamber to generate a capacitively coupled plasma in the processing chamber, and by attracting ions of the plasma generating gas to the target substrate where the metal thin film is deposited, after depositing the metal thin film, in a state where the generating of the inductively coupled plasma using the inductively coupled plasma generating mechanism and the power supply from the DC power source are stopped.

Yet another exemplary embodiment of the present disclosure provides a film forming apparatus which includes a processing chamber configured to receive a target substrate, a placing table configured to dispose the target substrate in the processing chamber, a gas introducing mechanism configured to introduce a plasma generating gas in the processing chamber, an inductively coupled plasma generating mechanism configured to generate an inductively coupled plasma of the plasma generating gas in the processing chamber, a metal target made of metal of a metallic film to be formed, a DC power source configured to supply DC power to the metal target, a bias power source configured to apply high-frequency bias to the placing table for attracting ions in the plasma generated in the processing chamber, and a control unit configured to deposit a metal thin film on the target substrate by generating the inductively coupled plasma in the processing chamber using the inductively coupled plasma generating mechanism while introducing the plasma generating gas in the processing chamber with the substrate loaded on the placing table, by supplying the DC power to the metal target from the DC power source, and by applying high-frequency bias to the placing table using the bias power source, and, after depositing the metal thin film, to resputter the deposited metal thin film by stopping the generating of the inductively coupled plasma using the inductively coupled plasma generating mechanism, by stopping the power supply from the DC power source, and by applying the high-frequency bias to the placing table using the bias power source while introducing the plasma generating gas in the processing chamber to generate a capacitively coupled plasma in the processing chamber and by attracting ions of the plasma generating gas to the target substrate where the metal thin film is deposited.

In the above exemplary embodiments, the high-frequency bias power for the resputtering may be 1500 W or more. Self biased voltage Vdc of the placing table for the resputtering may be 500 V or more. The deposited metal thin film may be a Cu film which is a seed film of a Cu wiring filled in the trenches and/or the holes. In the film forming apparatus according to yet another exemplary embodiment, the placing table of the film forming apparatus may include an electrode part installed to correspond with the target substrate, to which the high-frequency bias is supplied and a conductive ring member installed around the electrode part, and the conductive ring member may have the same potential as the electrode part. The placing table may have a shield ring installed at the outer circumference of the conductive ring member and the shield ring may serve as an opposing electrode of the electrode part when forming the capacitively coupled plasma in the processing chamber.

Still another exemplary embodiment of present disclosure provides a storage medium operating on a computer and storing a program for controlling a film forming apparatus, in which the program is executed by the computer to control the film forming apparatus so as to perform the film forming method according to the above exemplary embodiment.

According to the exemplary embodiments of the present disclosure, after the metal thin film is deposited with the inductively coupled plasma mode, a resputtering is performed with the capacitively coupled plasma mode in a state where the Vdc of the placing table is significantly large. As a result, it is possible to etch the film at the shoulders of the trenches or the holes at a large facet angle by attracting the ions of the plasma generating gas. Therefore, it is possible to prevent the overhang from being formed by reattaching particles of the resputtered film around the entrances of the trenches or the holes.

Hereinafter, exemplary embodiments of the present disclosure will be described in detail with reference to the accompanying drawings.

<Configuration of Film Forming Apparatus>

First, an example of a film forming apparatus will be described which performs a film forming method according to an exemplary embodiment of the present disclosure.

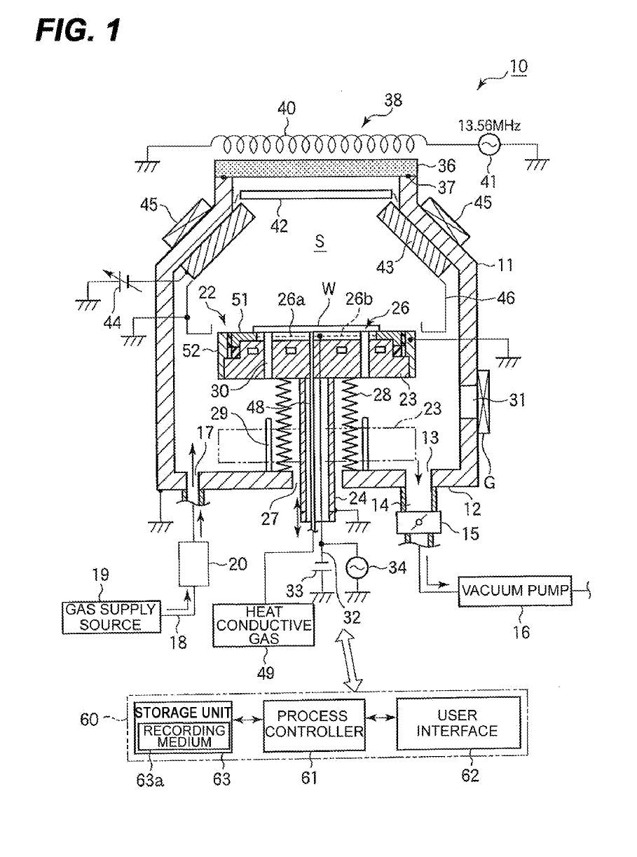

FIG. 1 is a cross-sectional view illustrating an example of a film forming apparatus that performs a film forming method according to an exemplary embodiment of the present disclosure.

A film forming apparatus 10 is configured as an inductively coupled plasma sputtering apparatus and includes a processing chamber 11 manufactured in a cylindrical body shape by, for example, aluminum. Processing chamber 11 is grounded, a vent hole 13 is installed in a bottom 12 of processing chamber 11, and a vent pipe 14 is connected to vent hole 13. A throttle valve 15 and a vacuum pump 16 which perform pressure control are connected to vent pipe 14, and the inside of processing chamber 11 becomes a vacuum state. A gas inlet port 17 that introduces a predetermined gas in processing chamber 11 is installed at bottom 12 of processing chamber 11. A gas supply pipe 18 is connected to gas inlet port 17 and a gas supply source 19 is connected to gas supply pipe 18. Gas supply source 19 may supply a noble gas, such as, for example, Ar gas, or other required gases, such as, N₂ gas, serving as a plasma generating gas. A gas control unit 20 including a gas flow controller and a valve is connected in gas supply pipe 18.

A disk-shaped placing table 22 configured to dispose a semiconductor wafer W (“a wafer W”) which is a target substrate is installed in a state where placing table 21 is supported to a grounded hollow cylindrical support 24 in processing chamber 11. Placing table 22 has a placing table body 23 as a main part thereof.

A thin disk-shaped electrostatic chuck 26 in which an electrode 26b is embedded in a dielectric member 26a, such as, for example, alumina, is installed at the upper side of placing table body 23. Electrostatic chuck 26 is configured such that voltage is applied to electrode 26b to adsorb and hold wafer W by an electrostatic force, and the voltage may be turned OFF to detach wafer W. A detailed description of placing table 22 will be described below.

The lower portion of support 24 passes through a through hole 27 formed at the center of bottom 12 of processing chamber 11 to extend downwards. Support 24 may move upwardly/downwardly by a lift mechanism (not shown) to ascend/descend placing table 22 accordingly.

A retractable bellows-shaped metal bellows 28 is installed to surround support 24, the upper end of metal bellows 28 is airtightly bonded to the lower surface of placing table body 23, and the lower end of metal bellows 28 is airtightly bonded to the upper surface of bottom 12 of processing chamber 11 so as to allow placing table 22 to ascend/descend while maintaining airtightness in processing chamber 11.

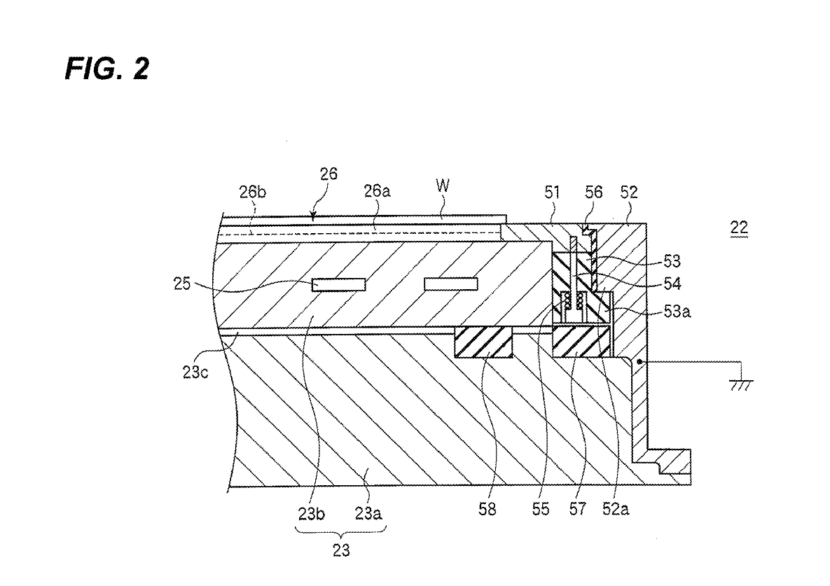

For example, three support pins 29 (only two support pins are shown in FIG. 2) are installed upwardly at bottom 12, and pin through holes 30 are formed in placing table body 23 to correspond with support pins 29. As a result, when placing table body 23 is descended, wafer W is disposed at the upper ends of support pins 29 passing through pin through holes 30 to be movably mounted between a transfer arm (not shown) transferred from the outside. As a result, a carrying in/out port 31 is installed at the lower side wall of processing chamber 11 so as to transfer the transfer arm, and a gate valve G capable of opening/closing is installed at carrying in/out port 31. For example, a vacuum transfer chamber (not shown) is connected through gate valve G.

A chuck power source 33 is connected to electrode 26b of electrostatic chuck 26 through a power supply line 32 and DC voltage is applied to electrode 26b from chuck power source 33, and, as a result, wafer W is adsorbed and held by the electrostatic force. Chuck power source 33 may be turned ON/OFF using a switch (not shown). In a state where wafer W is adsorbed, wafer W may be detached if the switch of chuck power source 33 is turned OFF. A bias high-frequency power source 34 is connected to power supply line 32 and bias high-frequency power is supplied to an electrode part 23b for biasing (see FIG. 2) through power supply line 32 to be applied to wafer W. A frequency of the high-frequency power may be 400 kHz to 60 MHz, and, for example, 13.56 MHz may be adopted.

A heat conductive gas such as Ar gas is supplied from a heat conductive gas supply source 49 to the rear side of wafer W adsorbed by electrostatic chuck 26 through a heat conductive gas channel 48 that supplies the heat conductive gas. Heat conductive gas channel 48 passes inside support 24 from the lower side of processing chamber 11, and passes through placing table body 23 and electrostatic chuck 26 to be extended. Heat conductive gas channel 49 is configured such that the heat conductive gas flows between wafer W and electrostatic chuck 26 when adsorbing wafer W by electrostatic chuck 26, thereby ensuring heat conduction to wafer W so that wafer W can be cooled.

Meanwhile, a dielectric plate 36 made of a dielectric material such as, for example, quartz, is airtightly installed on a ceiling part of processing chamber 11 through a sealing member 37 such as an O ring. A plasma generating source 38 is installed above dielectric plate 36 to generate plasma by converting the noble gas such as, for example, Ar gas serving as a plasma excitation gas into plasma in a processing space S of processing chamber 11. Another noble gas, such as, for example, He gas, Ne gas or Kr gas instead of Ar gas may be used as the plasma excitation gas.

Plasma generating source 38 includes an induction coil 40 installed to correspond with dielectric plate 36, a high-frequency power source 41 of, for example, 13.56 MHz is connected to induction coil 40 for plasma generation, and an inductive electric field is generated in processing space S through dielectric plate 36 when the high-frequency power is introduced to induction coil 40.

A baffle plate 42 made of a material such as, for example, aluminum is installed directly under dielectric plate 36 for diffusing the introduced high-frequency power. An annular (truncated conical shell-shaped) target 43 made of metal of a film to be formed is installed below baffle plate 42, and the cross section of annular target 43 is inclined inwardly by surrounding the upper lateral side of processing space S. A variable-voltage controlled DC power source 44 is connected to target 43 for supplying DC power to attract Ar ions. Alternatively, an AC power source instead of the DC power source may be used.

A magnet 45 that applies a magnetic field is installed at the outer circumference side of target 43. Target 43 is sputtered by Ar ions in the plasma to become metal atoms or atom groups, and most of the metal atoms or the atom groups are ionized when passing through the plasma.

A cylindrical protective cover member 46 made of, for example, aluminum or copper which surrounds processing space S, is installed below target 43. Protective cover member 46 is grounded and the lower portion thereof is bent inwardly to be disposed around the side of placing table 22. Accordingly, an internal end of protective cover member 46 is installed by surrounding the outer peripheral side of placing table 22.

Film forming apparatus 10 is controlled by a control unit 60 including a process controller 61 configured by a microprocessor (computer) that executes a control of each constituent unit, a user interface 62 configured by, for example, a keyboard that allows an operator to perform, for example, an input control of a command in order to manage the apparatus and by a display that visualizes and displays an operation situation of the apparatus, and a storage unit 63 that stores a control program for implementing the process executed by film forming apparatus 10 by the control of process controller 61 or stores a program for executing the process in each constituent unit of the processing apparatus according to various data and processing conditions, that is, a recipe. User interface 62 and storage unit 63 are connected to process controller 61.

The recipe is stored in a recording medium 63a of storage unit 63. The recording medium may be a hard disk, and also be a CD-ROM, a DVD, a flash memory, and a blue-ray disk (BD) which have portability. Alternatively, the recipe may appropriately be transmitted from another apparatus through, for example, a dedicated line.

As necessary, any recipe is read from storage unit 63 by, for example, an instruction from user interface 62 to be performed in process controller 61, such that a desired processing is performed by film forming apparatus 10 under the control of process controller 61.

Next, a detailed structure of placing table 22 will be described with reference to FIG. 2.

Placing table body 23 which is a main part of placing table 22 includes a base part 23a and electrode part 23b installed thereon. The surface of electrode part 23b is made of a material such as, for example, anodized aluminum to which a bias may be applied. Electrode part 23b is installed to support the electrostatic chuck, a cooling jacket 25 serving as a cooling mechanism is installed in the electrode part 23b, and a cooling medium is supplied through a cooling medium channel (not shown). As for the cooling medium, galden may be appropriately used and electrode part 23b is controlled at a desired temperature by supplying the cooling medium.

Placing table 22 includes a bias ring 51 installed around electrostatic chuck 26 and made of a conductive material such as aluminum or an aluminum alloy, and a ring-shaped shield member 52 installed at the outside of bias ring 51 and formed with a conductive material such as aluminum and an aluminum alloy that forms an outermost circumference of placing table 22. Bias ring 51 and shield member 52, insulated from each other by an insulating member 56, are fixed to base part 23a of placing table body 23.

The anodized thin film is peeled on the contact surface of electrode part 23b of placing table body 23 with bias ring 51, and thus, electrode part 23b and bias ring 51 are conductively communicated with each other. A ring-shaped insulating member 53 is installed between electrode part 23b and shield member 52. Insulating member 53 has a step part 53a corresponding with a step part 52a formed at the inner circumference of shield member 52, and, as a result, upward movement of insulating member 53 is suppressed. A support member 54 screw-fixed to bias ring 51 is movably fitted in insulating member 53 and support member 54 is pressed downwardly by a coil spring 55 installed inside insulating member 53. Accordingly, bias ring 51 is pressed downwardly together with support member 54 by a compressed force of coil spring 55, and bias ring 51 is pressed to electrode part 23b. As a result, electrode part 23b and bias ring 51 are sufficiently conductively communicated with each other, and, when a high-frequency bias is applied to electrode part 23b, electrode part 23b and bias ring 51 become almost an equipotential, such that a stable resputtering is available.

A ring-shaped insulating member 57 is interposed between insulating member 53 and base part 23a so as to insulate therebetween, and a ring-shaped insulating member 58 is installed between electrode part 23b and base part 23a at a position which is inner side than insulating member 57, and, as a result, a space part 23c is formed between electrode part 23b and base part 23a.

<Film Forming Method>

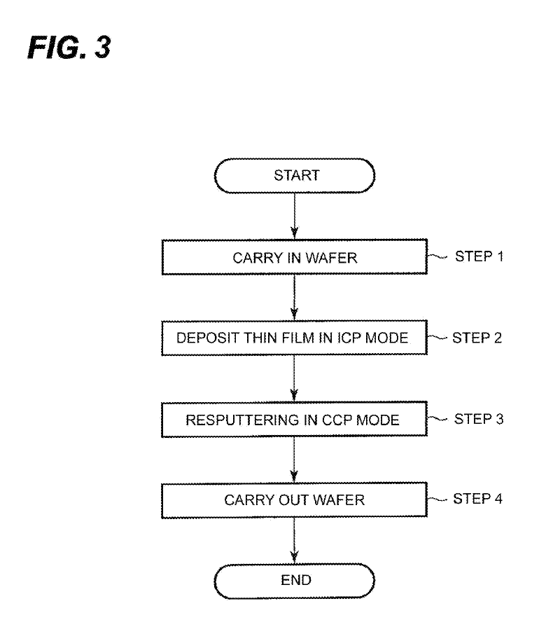

Next, a film forming method that can be performed in film forming apparatus 10 as described above will be described with reference to a flowchart of FIG. 3. Herein, a case will be described, where, for example, a Cu seed film is formed on a wafer having trenches and/or holes.

First, wafer W is carried in to processing chamber 11 as shown in FIG. 1 and disposed on placing table 22 maintained at a relatively low temperature by a cooling medium supplied to cooling jacket 25 which is a cooling mechanism (Step 1).

While Ar gas serving as plasma generating gas flows into processing chamber 11 which is in a predetermined vacuum state by operating vacuum pump 16, at a predetermined flow by operating gas control unit 20, the gas is stabilized by controlling throttle valve 15, wafer W is adsorbed to electrostatic chuck 26 by applying voltage, and heat conductive gas flows in the rear surface of wafer W. In this case, placing table body 23 is controlled by the cooling medium at a temperature of, for example, −50° C. to 0° C., and, specifically −30° C. to 0° C.

In this state, the Cu seed film is deposited for the first time in an inductively coupled plasma mode (Step 2).

In the depositing process at Step 2, in the state where the Ar gas flows, high-frequency power source 41 is turned ON to supply high-frequency power to induction coil 40 and generate inductively coupled plasma in processing chamber 11. And, then, DC power source 44 is turned ON to supply predetermined DC power to target 43. Subsequently, the flow rate of Ar gas is increased up to a flow used at a film forming process, and the bias high-frequency power is supplied to placing table body 23 by turning ON bias high-frequency power source 34 while controlling the DC power supplied to target 43, thereby depositing the Cu particles discharged from the target on wafer W.

When the DC power is applied to target 43 in the deposition process, the Ar ions in the inductively coupled plasma are attracted by the DC voltage to collide with target 43, thereby sputtering target 43 to discharge Cu particles. In this case, the amount of discharged Cu is appropriately controlled by the DC voltage applied to target 43. Most of the Cu particles discharged from target 43 are ionized when passing through the plasma. The ionized Cu ions and neutral Cu atoms having electrical neutrality are mixed with each other to be dispersed downwardly. In this case, an ionization ratio is controlled by the high-frequency power supplied from high-frequency power source 41.

When the Cu ions enter into an ion-sheath area having a thickness of about several mm and formed on wafer W by the bias high-frequency power for biasing applied to electrode part 23b from high-frequency power source 34, the ions are attracted so as to be accelerated toward wafer W with strong directivity to be deposited on wafer W, thereby forming a Cu film. In this case, the Ar ions are also attracted toward wafer W by the bias high-frequency power, but the Cu film serving as the seed film is deposited at a desired film-forming rate by controlling the bias power to control the Cu deposition and an etching by Ar gas.

Since the inductively coupled plasma is high-density plasma, ions may be generated at high density and the Cu film may be formed at high film-forming rate. When the seed film is formed, a film thickness may be, for example, 20 nm to 30 nm.

Conditions for the film-forming process at Step 2 are as follows.

Ar gas flow: 130 sccm to 750 sccm (e.g., 215 sccm)

High-frequency power for ICP: 4000 W to 5250 W (e.g., 5250 W)

DC power for target: 6000 W to 18000 W (e.g., 12000 W)

Bias high-frequency power: 50 W to 300 W (e.g., 200 W)

Pressure in processing chamber: 5.0 mTorr to 90.0 mTorr (e.g., 35 mTorr)

After forming the film in the inductively coupled plasma mode, a resputtering is performed in a capacitively coupled plasma mode as described below (Step 3).

In the resputtering process at Step 3, after deposition of the Cu film, bias high-frequency power source 34 is turned OFF, DC power source 44 is turned OFF, high-frequency power source 41 for inductively coupled plasma is turned OFF, and then the Ar gas flow is controlled. The resputtering is then performed for a predetermined time, for example, 5 sec to 30 sec by decreasing the Ar gas flow after the capacitively coupled plasma is generated by supplying the high-frequency power (applying the high-frequency bias) from bias high-frequency power source 34. By the resputtering process, the bottom or the shoulder of the deposited Cu film is sputtered and redeposited to the side wall of the trenches or the holes, thereby forming a Cu film having a controlled distribution in the film thickness, e.g., having a thick film thickness in the side wall.

Conditions in the resputtering process at Step 3 are as follows.

Ar gas flow: 55 sccm to 500 sccm (e.g., 55 sccm)

Bias high-frequency power: 1500 W to 2500 W (e.g., 2400 W)

Pressure in processing chamber: 2.5 mTorr to 15 mTorr (e.g., 2.5 mTorr)

After the resputtering is performed, bias high-frequency power source 34 is turned OFF, and, after a dechuck processing is performed by electrostatic chuck 26, the power supply to electrostatic chuck 26 is turned OFF to descend placing table 22 and to open gate valve G, thereby carrying out wafer W (Step 4).

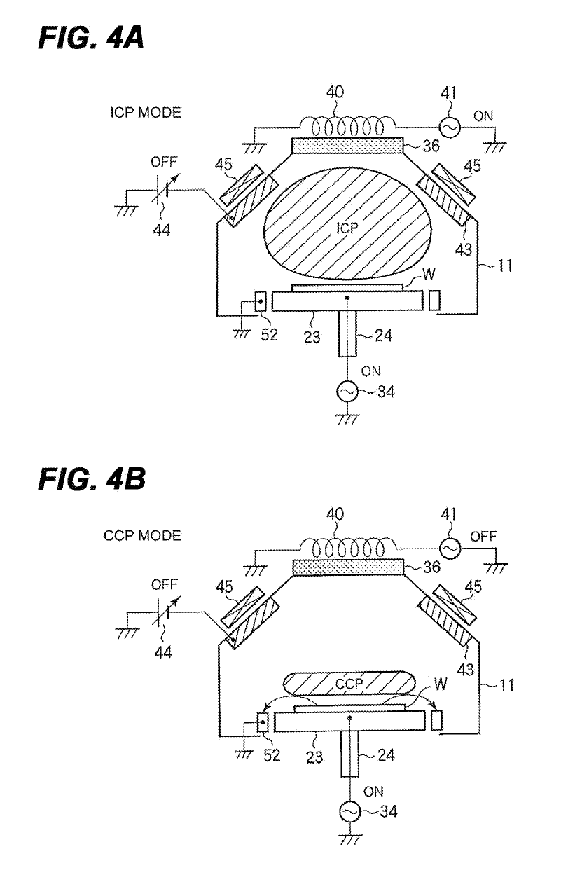

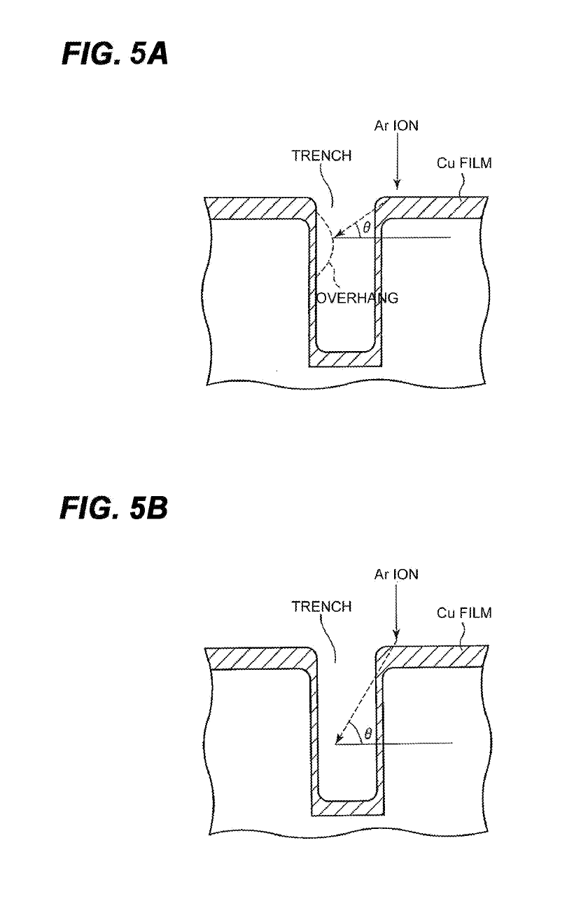

As described above, since the deposition to the side wall of the trenches or the holes tends to be insufficient at the film forming process by the plasma sputtering, the resputtering is generally performed after the deposition. Heretofore, regarding the resputtering after the deposition is completed, the supply of DC power to the target is stopped, and Ar ions are attracted to wafer W in an inductively coupled plasma mode to perform the resputtering. However, when the resputtering is performed in the inductively couple plasma mode, as shown in FIG. 4A, the acceleration of the Ar ions is small since the inductively coupled plasma having high plasma density (for example, 1×10¹² atoms/cm³) is formed in the entire processing space and the self biased voltage Vdc of wafer W is small as 100 V or less due to an inherently thin plasma sheath. Accordingly, as shown in FIG. 5A, facet angles θ of the Ar ions attracted to the shoulder of the trenches decrease and the Cu particles etched from the shoulder is reattached to the inner wall around the entrance of the trenches or the holes, such that the overhang may occur.

As a result of the study, it has been found out that the problem as discussed above can be solved by performing the resputtering using the capacitively coupled plasma. That is, resputtering is performed in a capacitively couple plasma mode in the present exemplary embodiment by turning OFF high-frequency power source 41 used for generating inductively coupled plasma. As a result, when the high-frequency power is supplied only to electrode part 23b of placing table body 23, as shown in FIG. 4B, shield member 52 being grounded serves as an opposing electrode, a high-frequency electric field is formed between the grounded shield member 52 and electrode part 23b to which the high-frequency power for biasing is supplied, and a flat capacitively coupled plasma is formed above wafer W. The capacitively coupled plasma has a plasma density of about 1 to 2 orders (for example, 1×10¹⁰ atoms/cm³) lower than that of the inductively coupled plasma in principle, such that the plasma sheath is thickly formed and the Vdc may have a significantly high value around 1000 V. As a result, as shown in FIG. 5B, since the facet angle θ increases and the Cu particles etched from the shoulder are formed to the lower side than the entrance of the trenches, it is difficult to form the overhang. The facet angle θ may be 50° or more, and, to this end, the Vdc of electrode part 23b may be 500 V or more. Shield member 52 serving as the opposing electrode is installed at a position close to electrode part 23b and has a certain area, such that the capacitively coupled plasma may be efficiently formed.

Differences between the inductively coupled plasma (ICP) mode and the capacitively couple plasma (CCP) mode are integrally represented by Table 1.

TABLE 1

| | ICP mode | CCP mode |
|---|---|---|
| Plasma density | High (1 × 10¹² atoms/cm³) | Medium to Low |
| | | (1 × 10¹⁰ atoms/cm³) |
| Vdc | Low (to 100 V) | High (to 1000 V) |

However, in the conventional apparatus, the anodized thin film is formed on the entire surface of electrode part 23b of placing table body 23, and electrode part 23b and bias ring 51 are not conductively communicated with each other. Accordingly, a potential difference is generated between electrode part 23b and bias ring 51.

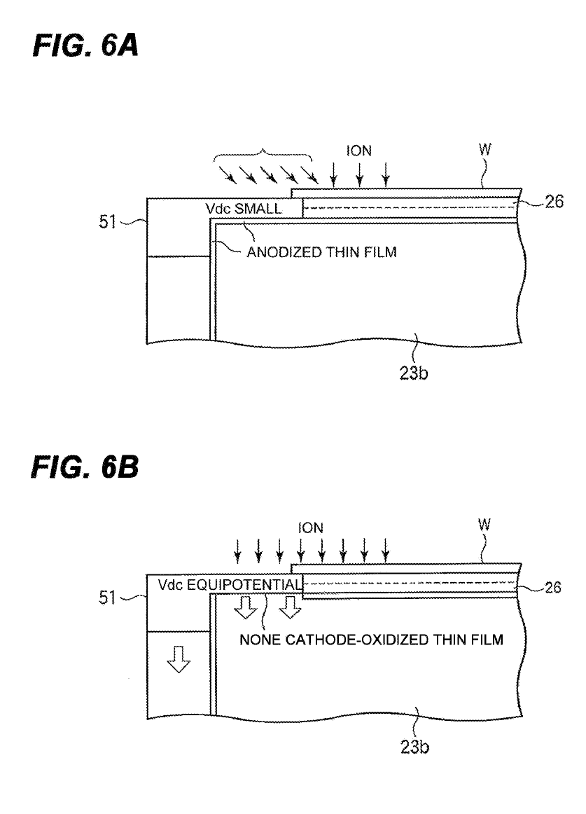

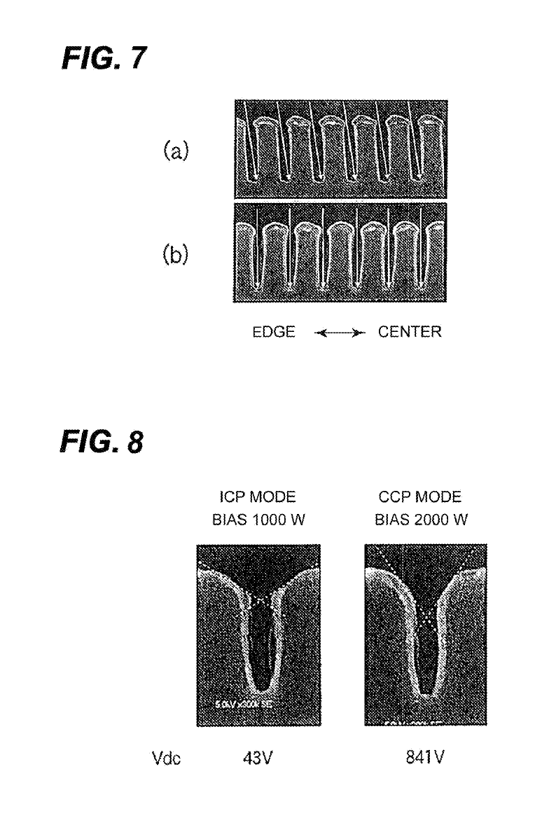

In the inductively coupled plasma mode, since the plasma sheath is thin and the Vdc is also small, the potential difference is not a big problem. However, as in the present exemplary embodiment, since the Vdc is large when performing the resputtering process in the capacitively coupled plasma mode, a Vdc potential difference between electrode part 23b and bias ring 51 disposed at the outside thereof increases. As a result, a slope of the electric field occurs at the edge of wafer W. Since the plasma sheath is thick, the distance where the ions are accelerated is lengthened. Accordingly, as shown in FIG. 6A, since the ions are obliquely attracted to the edge of wafer W, a uniform etching is difficult in the resputtering that uses Ar ions. That is, as shown in the scanning electron micrograph (SEM) photograph of FIG. 7(a), the ions are obliquely attracted to wafer W in the resputtering, and as a result, only one side of the film formed at the shoulder of the trenches, is etched to be asymmetrical.

In the present exemplary embodiment, the anodized thin film is peeled from the contact surface with bias ring 51 in electrode part 23b, and bias ring 51 is pressurized to electrode part 23b by coil spring 55, such that a good conductive communication is ensured between electrode part 23b and bias ring 51, and the Vdc of electrode part 23b and the Vdc of bias ring 51 become almost the same as each other.

Accordingly, the slope of the electric field in the edge of wafer W does not occur, and, as shown in FIG. 6B, the ions may be vertically attracted even to the edge of wafer W. As a result, as shown in the SEM photograph of FIG. 7(b), the film formed at the shoulder of the trenches may be symmetrically etched in the resputtering.

<Experimental Result>

Next, experimental results will be described regarding the states of the Cu film formed with resputtering performed in the inductively coupled plasma (ICP) mode as in the related art and in the capacitively coupled plasma (CCP) mode as in the present exemplary embodiment, after forming the Cu film.

Conditions of the resputtering were as follows.

<ICP Mode>

Pressure in processing chamber: 2.5 mTorr

High-frequency power for ICP: 1000 W

Bias high-frequency power: 1000 W

Ar gas flow: 55 sccm

### <CCP Mode>

Pressure in processing chamber: 10 mTorr

High-frequency power for ICP: OFF

Bias high-frequency power: 2000 W

Ar gas flow: 300 sccm

As a result of performing the resputtering process under the above conditions, the Vdc was a low value of 43 V in the inductively coupled plasma mode, but was a very high value of 841 V in the capacitively coupled plasma mode. A SEM photograph of the trenches after resputtering is shown in FIG. 8. Since the Vdc was low in the inductively coupled plasma mode, the facet angle θ was around 30° and the overhang was formed around the entrance of the trenches. In contrast, since the Vdc was high in the capacitively coupled plasma mode and the facet angle θ reached up to approximately 60°, the overhang was not formed and the film of the side wall was formed to be thick.

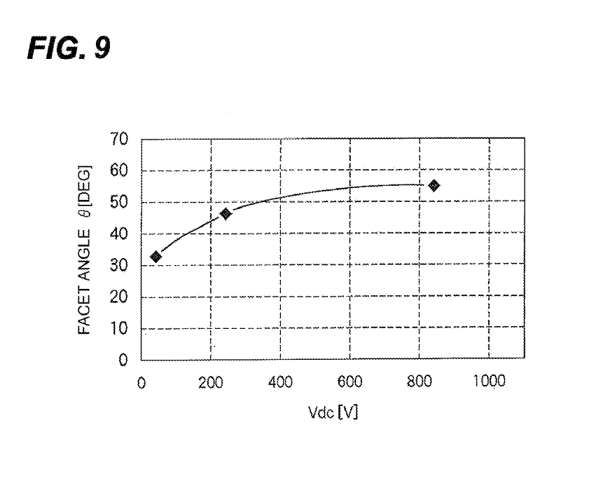

FIG. 9 is a graph illustrating a relationship between self biased voltage Vdc and a facet angle. As shown in FIG. 9, the facet angle increases as the Vdc increases. The facet angle θ may be 50° or more, and from this point of view, the Vdc may be 500 V or more.

<Other Applications>

As set forth above, although the exemplary embodiments of the present disclosure have been described, the present disclosure is not limited to the above exemplary embodiments, and may be variously modified. For example, the exemplary embodiments of the present disclosure are applied to the forming of the Cu seed film, but the present disclosure is not limited thereto, and may be applied to any case where the metal thin film (including a metallic compound) is formed in the trenches or the holes of the target substrate. For example, the present disclosure may also be applied to the film forming of Ta, Ti, TaN and TiN which are used as the bather film of the Cu wiring.

In the exemplary embodiments described above, the semiconductor wafer is described as the target substrate, but the semiconductor wafer may be one of compound semiconductors such as GaAs, SiC, and GaN as well as silicon. The present disclosure is not limited to the semiconductor wafer, but may also be applied to a glass substrate used in a flat panel display (FPD) of a liquid crystal display device, or a ceramic substrate.

The present disclosure may be applied to a formation of a logic semiconductor device such as MPU, or a memory device such as DRAM, and NAND. The present disclosure may also be applied to a wiring formation of a new memory device such as PRAM and MeRAM.

From the foregoing, it will be appreciated that various embodiments of the present disclosure have been described herein for purposes of illustration, and that various modifications may be made without departing from the scope and spirit of the present disclosure. Accordingly, the various embodiments disclosed herein are not intended to be limiting, with the true scope and spirit being indicated by the following claims.

What is claimed is:

1. A film forming method of forming a metal thin film on a target substrate having trenches and/or holes by using a film forming apparatus including a processing chamber in which the target substrate is received, a placing table configured to dispose the target substrate in the processing chamber, a gas introducing mechanism configured to introduce a plasma generating gas in the processing chamber, an inductively coupled plasma generating mechanism configured to generate an inductively coupled plasma of the plasma generating gas in the processing chamber, a metal target made of metal of a metallic film to be formed, a DC power source configured to supply DC power to the metal target, and a bias power source configured to apply high-frequency bias for attracting ions in the plasma generated in the processing chamber to the placing table, the method comprising:
depositing the metal thin film on the target substrate by generating the inductively coupled plasma in the processing chamber using the inductively coupled plasma generating mechanism while introducing the plasma generating gas in the processing chamber with the target substrate disposed on the placing table, by supplying the DC power to the metal target from the DC power source, and by applying high-frequency bias to the placing table using the bias power source; and
resputtering the deposited metal thin film by stopping the generating of the inductively coupled plasma generated using the inductively coupled plasma generating mechanism, by stopping the power supply from the DC power source, by applying the high-frequency bias to the placing table by the bias power source while introducing the plasma generating gas in the processing chamber to generate a capacitively coupled plasma in the processing chamber, and by attracting ions of the plasma generating gas to the target substrate where the metal thin film is deposited.

2. The film forming method of claim 1, wherein the high-frequency bias power for the resputtering is 1500 W or more.

3. The film forming method of claim 1, wherein self biased voltage Vdc of the placing table for the resputtering is 500 V or more.

4. The film forming method of claim 1, wherein the deposited metal thin film is a Cu film which is a seed film of a Cu wiring to be filled in the trenches and/or the holes.

5. A resputtering method of resputtering a metal thin film after depositing the metal thin film on a target substrate having trenches and/or holes by using a film forming apparatus including a processing chamber in which the target substrate is received, a placing table configured to dispose the target substrate in the processing chamber, a gas introducing mechanism configured to introduce a plasma generating gas in the processing chamber, an inductively coupled plasma generating mechanism configured to generate an inductively coupled plasma of the plasma generating gas in the processing chamber, a metal target made of metal of a metallic film to be formed, a DC power source configured to supply DC power to the metal target, and a bias power source configured to apply high-frequency bias for attracting ions in the plasma generated in the processing chamber to the placing table, the method comprising:
resputtering the deposited metal thin film by applying the high-frequency bias to the placing table using the bias power source while introducing the plasma generating gas in the processing chamber to generate a capacitively coupled plasma in the processing chamber and by attracting ions of the plasma generating gas to the target substrate where the metal thin film is deposited, after depositing the metal thin film, in a state where the generating of the inductively coupled plasma using the inductively coupled plasma generating mechanism and the power supply from the DC power source are stopped.

6. The resputtering method of claim 5, wherein the high-frequency bias power is 1500 W or more.

7. The resputtering method of claim 5, wherein self biased voltage Vdc of the placing table is 500 V or more.

8. The resputtering method of claim 5, wherein the metal thin film deposited on the target substrate is a Cu film which is a seed film of a Cu wiring to be filled in the trenches and/or the holes.

9. A film forming apparatus, comprising:
a processing chamber configured to receive a target substrate;
a placing table configured to dispose the target substrate in the processing chamber;
a gas introducing mechanism configured to introduce a plasma generating gas in the processing chamber;
an inductively coupled plasma generating mechanism configured to generate an inductively coupled plasma of the plasma generating gas in the processing chamber;
a metal target made of metal of a metallic film to be formed;
a DC power source configured to supply DC power to the metal target;
a bias power source configured to apply high-frequency bias to the placing table for attracting ions in the plasma generated in the processing chamber; and
a control unit configured to deposit a metal thin film on the target substrate by generating the inductively coupled plasma in the processing chamber using the inductively coupled plasma generating mechanism while introducing the plasma generating gas in the processing chamber with the substrate disposed on the placing table, by supplying the DC power to the metal target from the DC power source, and by applying high-frequency bias to the placing table using the bias power source, and, after depositing the metal thin film, to resputter the deposited metal thin film by stopping the generating of the inductively coupled plasma using the inductively coupled plasma generating mechanism, by stopping the power supply from the DC power source, by applying the high-frequency bias to the placing table using the bias power source while introducing the plasma generating gas in the processing chamber to generate a capacitively coupled plasma in the processing chamber and by attracting ions of the plasma generating gas to the target substrate where the metal thin film is deposited.

10. The film forming apparatus of claim 9, wherein the control unit controls the high-frequency bias power for the resputtering to be 1500 W or more.

11. The film forming apparatus of claim 9, wherein the control unit controls self biased voltage Vdc of the placing table for the resputtering to be 500 V or more.

12. The film forming apparatus of claim 9, wherein the deposited metal thin film is a Cu film which is a seed film of a Cu wiring to be filled in the trenches and/or the holes formed on the target substrate.

13. The film forming apparatus of claim 9, wherein the placing table includes an electrode part installed to correspond with the target substrate, to which the high-frequency bias is supplied and a conductive ring member installed around the electrode part and the conductive ring member has the same potential as the electrode part.

14. The film forming apparatus of claim 13, wherein the placing table has a shield ring installed at the outer circumference of the conductive ring member and the shield ring serves as an opposing electrode of the electrode part when forming the capacitively coupled plasma in the processing chamber.

15. A storage medium operating on a computer and storing a program for controlling a film forming apparatus, wherein the program is executed by the computer to control the film forming apparatus so as to perform the film forming method of claim 1.
